(19) United States
(12) Patent Application Publication
(10) Pub. No.: US 2018/0068926 A1
(43) Pub. Date: Mar. 8, 2018

(54) ENERGY STORAGE MATERIAL FOR THERMAL MANAGEMENT AND ASSOCIATED TECHNIQUES AND CONFIGURATIONS

(71) Applicant: INTEL CORPORATION, SANTA CLARA, CA (US)

(72) Inventors: JAN KRAJNIAK, Gilbert, AZ (US); TANNAZ HARIRCHIAN, Chandler, AZ (US); KELLY P. LOFGREEN, Phoenix, AZ (US); JAMES C. MATAYABAS, Jr., Gilbert, AZ (US); NACHIKET R. RARAVIKAR, Gilbert, AZ (US); ROBERT L. SANKMAN, Phoenix, AZ (US)

(21) Appl. No.: 15/553,932

(22) PCT Filed: Mar. 27, 2015
(86) PCT No.: PCT/US2015/023182

§ 371 Date: Aug. 25, 2017

(51) Int. Cl. H01L 23/427; H01L 23/373; H01L 21/77

(52) U.S. Cl. CPC H01L 23/427; H01L 23/373; C09K 5/02; H01L 23/3737; H01L 21/77

(57) ABSTRACT

Embodiments of the present disclosure describe an energy storage material for thermal management and associated techniques and configurations. In one embodiment, an energy storage material may include an organic matrix and a solid-solid phase change material dispersed in the organic matrix, the solid-solid phase change material to change crystalline structure and absorb heat while remaining a solid at a threshold temperature associated with operation of an integrated circuit (IC) die. Other embodiments may be described and/or claimed.

### FIELD

Embodiments of the present disclosure generally relate to the field of integrated circuit (IC) assemblies, and more particularly, to energy storage material for thermal management and associated techniques and configurations.

### BACKGROUND

Mobile devices such as handheld phones or tablets may not have active thermal management solutions. Instead, heat generated by circuitry may be passively distributed throughout the device and dissipated into the environment. Depending on a type of device operation and corresponding power output pattern, either a junction temperature at the circuitry or a skin temperature may become a performance limiting factor. For example, the junction temperature may become a bottleneck when a burst of high power from a chip for rendering graphics, opening an application, changing website, and the like occurs. Current thermal pathways may be insufficient to rapidly conduct heat to the bulk of the device resulting in hot spots on the chip and potentially leading to power throttling and/or decreased performance. The skin temperature may become a bottleneck when a power burst is low and the mobile device is operating at steady state conditions for extended periods of time. For example, steady heat generation from the chip may cause formation of hot spots on a skin of the device, which may exceed ergonomically acceptable temperature ranges and potentially result in limited device performance to keep the skin temperature below an acceptable limit.

The background description provided herein is for the purpose of generally presenting the context of the disclosure. Unless otherwise indicated herein, the materials described in this section are not prior art to the claims in this application and are not admitted to be prior art by inclusion in this section.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section side view of an example integrated circuit (IC) assembly, in accordance with some embodiments.

FIG. 2 schematically illustrates a cross-section side view of a mobile device including an IC assembly, in accordance with some embodiments.

FIG. 3 schematically illustrates an energy storage material, in accordance with some embodiments.

FIG. 4 schematically illustrates an arrangement of layers for thermal management in a mobile device, in accordance with some embodiments.

FIG. 5 schematically illustrates graphs showing phase transition characteristics of some example solid-solid phase change materials, in accordance with some embodiments.

FIG. 6 schematically illustrates a graph showing phase transition characteristics of Field's metal, in accordance with some embodiments.

FIG. 7 schematically illustrates a flow diagram for a method of fabricating an energy storage material, in accordance with some embodiments.

FIG. 8 schematically illustrates a computing device that includes an IC assembly as described herein, in accordance with some embodiments.

### DETAILED DESCRIPTION

Embodiments of the present disclosure describe an energy storage material for thermal management and associated techniques and configurations. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group), and/or memory (shared, dedicated, or group) that execute one or more software or firmware programs, a combinational logic circuit, and/or other suitable components that provide the described functionality. As used herein, the term “substrate” may refer to any suitable structure upon which energy storage material may be disposed.

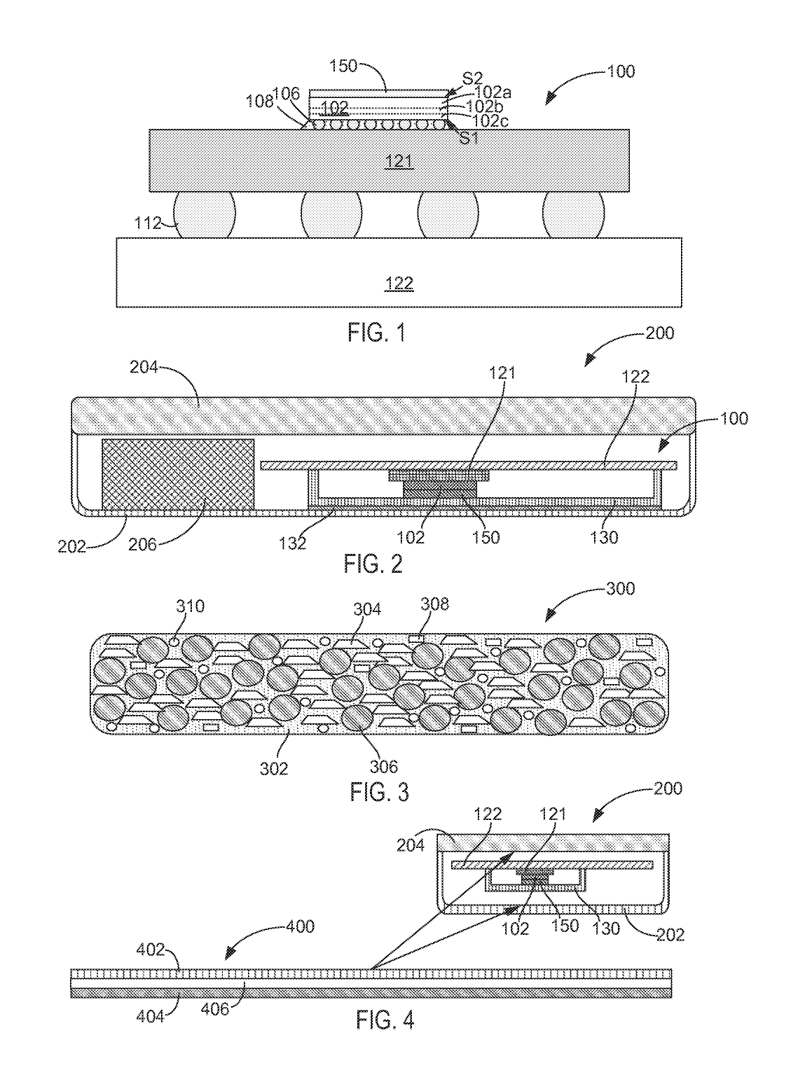

FIG. 1 schematically illustrates a cross-section side view of an example integrated circuit (IC) assembly 100, in accordance with some embodiments. In some embodiments, the IC assembly 100 may include one or more dies (hereinafter “die 102”) electrically and/or physically coupled with an IC substrate 121 (sometimes referred to as a “package substrate”). In some embodiments, the IC substrate 121 may be electrically coupled with a circuit board 122, as can be seen. A heat transfer layer 150 may be formed on the die 102 to conduct heat that is generated during operation of the die away from the die. The heat transfer layer 150 may comport with embodiments described herein and may include, for example, materials such as the energy storage material of FIG. 3.

The die 102 may represent a discrete product made from a semiconductor material (e.g., silicon) using semiconductor fabrication techniques such as thin film deposition, lithography, etching, and the like used in connection with forming complementary metal-oxide-semiconductor (CMOS) devices. In some embodiments, the die 102 may be, include, or be a part of a radio frequency (RF) die. In other embodiments, the die may be, include, or be a part of a processor, memory, SoC, or ASIC.

In some embodiments, an underfill material 108 (sometimes referred to as an “encapsulant”) may be disposed between the die 102 and the IC substrate 121 to promote adhesion and/or protect features of the die 102 and IC substrate 121. The underfill material 108 may be composed of an electrically insulative material and may encapsulate at least a portion of the die 102 and/or die-level interconnect structures 106, as can be seen. In some embodiments, the underfill material 108 is in direct contact with the die-level interconnect structures 106.

The die 102 can be attached to the IC substrate 121 according to a wide variety of suitable configurations including, for example, being directly coupled with the IC substrate 121 in a flip-chip configuration, as depicted. In the flip-chip configuration, an active side, S1, of the die 102 including active circuitry is attached to a surface of the IC substrate 121 using die-level interconnect structures 106 such as bumps, pillars, or other suitable structures that may also electrically couple the die 102 with the IC substrate 121. The active side S1 of the die 102 may include transistor devices, and an inactive side, S2, may be disposed opposite to the active side S1, as can be seen.

The die 102 may generally include a semiconductor substrate 102a, one or more device layers (hereinafter “device layer 102b”), and one or more interconnect layers (hereinafter “interconnect layer 102c”). The semiconductor substrate 102a may be substantially composed of a bulk semiconductor material such as, for example, silicon, in some embodiments. The device layer 102b may represent a region where active devices such as transistor devices are formed on the semiconductor substrate 102a. The device layer 102b may include, for example, structures such as channel bodies and/or source/drain regions of transistor devices. The interconnect layer 102c may include interconnect structures that are configured to route electrical signals to or from the active devices in the device layer 102b. For example, the interconnect layer 102c may include trenches and/or vias to provide electrical routing and/or contacts.

In some embodiments, the die-level interconnect structures 106 may be configured to route electrical signals between the die 102 and other electrical devices. The electrical signals may include, for example, input/output (I/O) signals and/or power/ground signals that are used in connection with operation of the die 102.

The IC substrate 121 may include electrical routing features (not shown in FIG. 1) such as, for example, traces, pads, through-holes, vias, or lines configured to route electrical signals to or from the die 102. For example, the IC substrate 121 may be configured to route electrical signals between the die 102 and the circuit board 122, or between the die 102 and another electrical component (e.g., another die, interposer, interface, component for wireless communication, etc.) coupled with the IC substrate 121. In some embodiments, the die 102 may be partially or fully embedded in the IC substrate 121. In some embodiments, the IC substrate 121 may be composed of build-up laminate layers of epoxy resin and the electrical routing features may be composed of copper. The IC substrate 121 and/or electrical routing features may be composed of other suitable materials in other embodiments.

The circuit board 122 may be a printed circuit board (PCB) composed of an electrically insulative material such as an epoxy laminate. For example, the circuit board 122 may include electrically insulating layers composed of materials such as, for example, polytetrafluoroethylene, phenolic cotton paper materials such as Flame Retardant 4 (FR-4), FR-1, cotton paper, and epoxy materials such as CEM-1 or CEM-3, or woven glass materials that are laminated together using an epoxy resin pre-preg material. Interconnect structures (not shown) such as traces, trenches or vias may be formed through the electrically insulating layers to route the electrical signals of the die 102 through the circuit board 122. The circuit board 122 may be composed of other suitable materials in other embodiments. In some embodiments, the circuit board 122 is a motherboard (e.g., motherboard 802 of FIG. 8).

Package-level interconnects such as, for example, solder balls 112 may be coupled with the IC substrate 121 and/or the circuit board 122 to form corresponding solder joints that are configured to further route the electrical signals between the IC substrate 121 and the circuit board 122. Other suitable techniques to physically and/or electrically couple the IC substrate 121 with the circuit board 122 may be used in other embodiments.

The IC assembly 100 may include a wide variety of other suitable configurations in other embodiments including, for example, suitable combinations of flip-chip and/or wire-bonding configurations, interposers, multi-chip package configurations including system-in-package (SiP) and/or package-on-package (PoP) configurations. Other suitable techniques to route electrical signals between the die 102 and other components of the IC assembly 100 may be used in some embodiments.

The heat transfer layer 150 may be referred to as a thermal interface material (TIM) layer or “gap pad” in some embodiments. In an embodiment, the heat transfer layer 150 may be disposed on the second side S2 of the die 102. In some embodiments, the heat transfer layer 150 may be coupled with other components such as, for example, an integrated heat spreader (IHS) element and/or protective cover such as an electromagnetic interference (EMI) shield. The heat transfer layer 150 may be coupled with other suitable components to provide a thermal pathway away from the die 102 to dissipate heat in other embodiments.

FIG. 2 schematically illustrates a cross-section side view of a mobile device 200 including an IC assembly 100, in accordance with some embodiments. According to various embodiments, the mobile device 200 may represent a wide variety of devices including, for example, a phone, handset, tablet, and the like. In the depicted embodiment, the mobile device 200 may include a housing structure (hereinafter “housing 202” and sometimes referred to as “skin”) coupled with a display 204. The housing 202 may house internal components such as, for example, a battery 206 and/or circuitry such as, for example, IC assembly 100. According to various embodiments, the housing 202 may have an external surface that may come into contact with skin of a user holding the mobile device 200. Although in the depicted embodiment, the housing 202 is a single, continuous structure, in other embodiments, the housing 202 may include multiple components or structures coupled together. The housing 202 may be composed of any suitable material including, for example, a metal or polymer, or combination thereof. The display 204 may be configured to display images based on information processed by one or more dies of the IC assembly 100.

According to various embodiments, the IC assembly 100 may comport with embodiments described in connection with FIG. 1. For example, the IC assembly 100 may include a die 102 coupled with an IC substrate 121, which may be coupled with a circuit board 122. Subject matter is not limited in this regard and the die 102 may be coupled with other suitable components in other suitable configurations in other embodiments. In some embodiments, a heat transfer layer 150 (e.g., gap pad) may be disposed on the die 102 and configured to route heat away from the die 102 towards the housing 202 when the die 102 is in operation. In some embodiments, the heat transfer layer 150 may be composed of an energy storage material (e.g., energy storage material 300 of FIG. 3) as described herein.

Another component such as, for example, an EMI shield 130 may be coupled with the heat transfer layer 150 and/or to the circuit board 122 to protect the circuitry housed within the EMI shield 130 such as, for example, the die 102 from electromagnetic interference. In some embodiments, the EMI shield 130 may be composed of a thermally conductive material to facilitate heat transfer away from the heat transfer layer 150 to the housing 202 of the mobile device 200. For example, in some embodiments, the EMI shield 130 may be thermally coupled with the housing 202 using a thermal grease 132 or other suitable thermal layer.

FIG. 3 schematically illustrates an energy storage material 300, in accordance with some embodiments. According to various embodiments, the energy storage material 300 may include an organic matrix material (hereinafter “organic matrix 302”) and a solid-solid phase change material 304. The energy storage material 300 may further include a solid-liquid phase change material 306 in some embodiments. The energy storage material 300 may further include a wax material 308 cross-linked with the organic matrix 302 and/or a thermally conductive inorganic filler (hereinafter “inorganic filler 310”). The energy storage material 300 may include additional components (not shown) such as, for example, catalysts, stabilizers, solvents and the like. Although the depicted energy storage material 300 shows a particular relative distribution, shape and size for the components of the energy storage material 300, such depiction is merely an example and the components of the energy storage material 300 may have a wide variety of other relative distributions, shapes and/or sizes according to various embodiments.

The organic matrix 302 may provide a polymer backbone structure of the energy storage material 300. In some embodiments, the organic matrix 302 may include a silicone material such as, for example, a silicone backbone structure material. For example, in some embodiments, the organic matrix 302 may be composed of polydimethylsiloxane (PDMS), alkyl methyl silicone (AMS), combinations thereof, or other suitable material.

According to various embodiments, the energy storage material 300 may include a solid-solid phase change material 304 dispersed in the organic matrix 302. For example, the solid-solid phase change material 304 may be mixed such that individual particles of the solid-solid phase change material 304 are randomly and/or substantially evenly dispersed within the energy storage material 300. The amount of solid-solid phase change material 304 in the energy storage material 300 can vary, and may depend upon the heat exchanges involved, such as the device cooling requirements and latent heat of phase change per mol of the solid-solid phase change material 304. In some embodiments, a weight % of solid-solid phase change material 304 in the energy storage material 300 may be in the range from 40% to 60%. The weight % of solid-solid phase change material 304 in the energy storage material 300 may have other values in other embodiments.

In some embodiments, the solid-solid phase change material 304 may be a solid-phase material that changes crystalline structure at a threshold temperature such that the material absorbs heat while remaining a solid-phase material. A latent heat or heat of transformation of the change in crystalline structure of the solid-solid phase change material 304 may be used to absorb heat generated by operation of an IC die, in some embodiments. In some embodiments, the solid-solid phase change material 304 may be composed of a material that is formulated to change crystalline structure and absorb heat while remaining a solid at a threshold temperature associated with operation of an IC die. For example, in some embodiments, the energy capture may be used to mitigate temperature increases from burst mode power output spikes of circuitry (e.g., of a mobile device 200 of FIG. 2), which may delay time to reach a critical junction temperature (Tj) of an IC die and prevent throttling of performance of the IC die. The mechanical properties of energy storage material 300 as a gap pad may remain sufficiently rigid such that risk of pump-out of molten material may be prevented or mitigated. Materials that transition to liquid phase may be at risk of void formation and pump out over time if encapsulation or pump-out prevention features are not included. Formation of voids or pump-out may decrease thermal performance of an energy storage material over time. Mobile devices may be more susceptible to pump out due to components such as, for example, an EMI shield that may flex with device use. In some embodiments, the energy capture may be used to extend a time to reach an ergonomically uncomfortable temperature (Tskin) beyond a typical single instance usage time of a mobile device, which may reduce or prevent a perception of discomfort by a user holding the mobile device.

In some embodiments, the solid-solid phase change material 304 may be composed of a polyol or combination of polyols. For example, the polyol may include materials such as, for example, 2,2-dimethyl-1,3-propanediol, neopentyl glycol, 1,1,1-tris(hydroxymethyl)ethane or pentaglycerine, or combinations thereof. In one embodiment, the polyol comprises a mixture of neopentyl glycol (NPG) and pentaglycerine (PG). According to various embodiments, a ratio of component solid-solid phase change materials 304 may be formulated to provide a desired threshold temperature. A ratio of NPG to PG may determine the threshold temperature (e.g., with enthalpies of transition >100 kJ/kg), allowing tuning of the threshold temperature for different applications. For example, in some embodiments, the solid-solid phase change material 304 may be selected and/or combined to provide a threshold temperature that is within a tight range (e.g., less than or equal to 10° C.) above a steady state operating temperature of an IC die, which may allow the solid-solid phase change material 304 to capture burst mode thermal energy and release the energy in a gradual manner to mitigate hot spot formation. The solid-solid phase change material 304 may include other suitable materials in other embodiments.

The solid-solid phase change material 304 may have a threshold temperature ranging from 30° C. to 90° C. where the solid-solid phase change material 304 changes from a non-crystalline solid material to a crystalline solid material upon heating to the threshold temperature. In some embodiments, the threshold temperature may range from 35° C. to 45° C. The threshold temperature may have other suitable ranges or values in other embodiments.

In some embodiments, the energy storage material 300 may further include an inorganic filler 310 to enhance bulk thermal conductivity by providing or enhancing a heat percolation path through the organic matrix 302. The inorganic filler 310 may include a wide variety of materials including, for example, alumina, aluminum, silver, copper, graphite, BN, AlN, SiC, diamond and/or other like materials. The inorganic filler 310 may have an average dimension (e.g., thickness) ranging from 10 microns to 300 microns and may vary based upon design requirements of a given device. Particle size of the inorganic filler 310 may be approximately ⅓^{rd} of the bond line thickness of the energy storage material pad, in some embodiments. The inorganic filler 310 may include other suitable materials and/or have other suitable dimensions in other embodiments. In some embodiments, the inorganic filler 310 may be implemented as part of the energy storage material 300 for an application where the energy storage material is directly thermally coupled with an IC die (e.g., a heat transfer layer 150 or “gap pad” on the die 102).

The energy storage material 300 may further include a wax material 308 cross-linked with the organic matrix 302. The wax material 308 may decrease interfacial resistance of the energy storage material 300 upon softening in response to heating, which may increase bulk thermal conductivity by increasing interfacial contact. The cross-linking of the wax material 308 with the organic matrix 302 may reduce or prevent flow of the wax material 308 when molten and instead may allow softening of the organic matric 302 with reduced risk of pump-out. In some embodiments, the wax material 308 may include a C20-C24 alpha-olefin wax. In some embodiments, cross-linking the wax material 308 with the organic matrix 302 may form alkyl methyl silicone (AMS) wax. In some embodiments, a stiffness, softening temperature and/or softened viscosity of the organic matrix 302 (e.g., AMS) may be based on a ratio of dimethylsiloxane to methylhydrosiloxane, an amount of cross-linker, and a chain length of the wax material 308 cross-linked into the organic matrix 302. In one embodiment, the ratio of dimethylsiloxane to methylhydrosiloxane is about 3:1. The wax material 308 may include other suitable materials in other examples. In some embodiments, the wax material 308 may be implemented as part of the energy storage material 300 for an application where the energy storage material is directly thermally coupled with an IC die (e.g., a heat transfer layer 150 or “gap pad” on the die 102).

The energy storage material 300 may further include a solid-liquid phase change material 306, which may include a thermally conductive filler in some embodiments. For example, in some embodiments, the solid-liquid phase change material 306 may include a phase change filler formulated to change from solid to liquid phase at a temperature that is greater than or equal to the threshold temperature at which the solid-solid phase change material 304 changes crystalline structure. The solid-liquid phase change material 306 may increase bulk conductivity and/or increase energy capture capacity of the energy storage material 300. For example, while an IC die operates within steady state temperatures, the solid-liquid phase change material 306 may act as a thermally conductive filler and if burst mode energy of the IC die exceeds the energy capture capacity of the solid-solid phase change material 304, the solid-liquid phase change material 306 may change phase from solid to liquid to capture excess heat. In some embodiments, a transition temperature of the solid-liquid phase change material 306 may correspond to a temperature value immediately above the threshold temperature of the solid-solid phase change material 304. A risk of molten material of the solid-liquid phase change material 306 is mitigated by the enclosure of the organic matrix 302. In some embodiments, the solid-liquid phase change material 306 may be implemented as part of the energy storage material 300 for an application where the energy storage material is directly thermally coupled with an IC die (e.g., a heat transfer layer 150 or “gap pad” on the die 102).

In some embodiments, the solid-liquid phase change material 306 may include an alloy such as, for example, Field's alloy (e.g., 51% indium, 32.5% bismuth and 16.5% tin) or other low melting point alloy. In some embodiments, the Field's alloy may have a melting temperature (e.g., transition temperature) of 62° C. The solid-liquid phase change material 306 may include other suitable materials and/or melting temperatures in other embodiments.

In some embodiments, the energy storage material 300 may have a thermal conductivity of ˜0.2 Watts/meter·Kelvin (W/m·K). The energy storage material 300 may have other suitable values for thermal conductivity in other embodiments.

FIG. 4 schematically illustrates an arrangement of layers 400 for thermal management in a mobile device 200, in accordance with some embodiments. Referring to FIGS. 3 and 4, in some embodiments (e.g., for Tskin thermal management), the energy storage material (e.g., energy storage material 300 of FIG. 3) may be deposited to form an energy storage layer 402 (which may be referred to as “heat transfer layer” herein) on a substrate. In some embodiments, the energy storage layer 402 may be disposed on a thermally conductive spreading material such as thermally conductive sheet 404 including, for example, a copper foil, aluminum foil, or a graphene sheet. The arrangement of the energy storage layer 402 on the thermally conductive spreading material may provide spreading in x-y dimensions of the thermally conductive sheet 404 while insulating and capturing z-direction thermal energy transfer.

A thickness of the energy storage layer 402 may be selected for thermal performance (e.g., skin temperature reduction) and/or for reducing or minimizing a skin heat spreader overall thickness. In some embodiments, a thickness of the energy storage layer 402 may be less than 1 millimeter (mm). The energy storage layer 402 may have other suitable thicknesses in other embodiments.

A thickness of the thermally conductive sheet 404 may be selected for thermal performance (e.g., skin temperature reduction) and/or for reducing or minimizing a skin heat spreader overall thickness. In some embodiments, the thermally conductive sheet 404 has a thickness of 100 microns or less. The thermally conductive sheet 404 may have other suitable thicknesses in other embodiments.

In some embodiments, the energy storage layer 402 may be disposed directly on the thermally conductive sheet 404. In some embodiments, the energy storage layer 402 may serve as the sole energy capture and insulating layer. In other embodiments, the energy storage layer 402 may serve as an adhesive layer to a thermally insulative layer 406 (may be referred to as “heat insulator layer” herein). That is, the energy storage layer 402 may be used by itself for energy storage and insulation or it may be further layered with an additional thermally insulating material such as, for example, a thermally insulative layer 406 including polyurethane sheet or foam. Polyurethane foam may have a similar thermal conductivity to air (e.g., ˜0.02 W/m·K). In some embodiments, the thermally insulative layer 406 may balance a loss of air-gap insulation. In some embodiments, the thermally insulative layer 406 may be used as compressible padding, which allows conductive layers (e.g., the energy storage layer 402 or the thermally conductive sheet 404) to contact heat generating components without damaging load transfer from flexing of skin material of the mobile device 200.

A thickness of the thermally insulative layer 406 may be selected for thermal performance (e.g., skin temperature reduction) and/or for reducing or minimizing a skin heat spreader overall thickness. In some embodiments, the thermally insulative layer 406 has a thickness less than 1 mm. The thermally insulative layer 406 may have other suitable thicknesses in other embodiments.

In some embodiments, the arrangement of layers 400 may be disposed on an inner surface of housing 202 (e.g., skin) of the mobile device 200. For example, the thermally conductive sheet 404 may be disposed on metal of the housing 202 and the energy storage layer 402 may be disposed between the thermally conductive sheet 404 and circuitry (e.g., IC die 102) of the mobile device 200. In another embodiment, arrangement of layers 400 may be disposed on an inner surface of the display 204. For example, the thermally conductive sheet 404 may be disposed on any suitable surface of the display 204 and the energy storage layer 402 may be disposed between the thermally conductive sheet 404 and circuitry (e.g., IC die 102) of the mobile device 200. The arrangement of layers 400 may be disposed on surfaces of the mobile device 200 according to other arrangements than described. For example, a reverse order of the arrangement of layers 400 may be disposed on surfaces of the mobile device 200 (e.g., the energy storage layer 402 may be disposed directly on the material of the housing 202 or display 204).

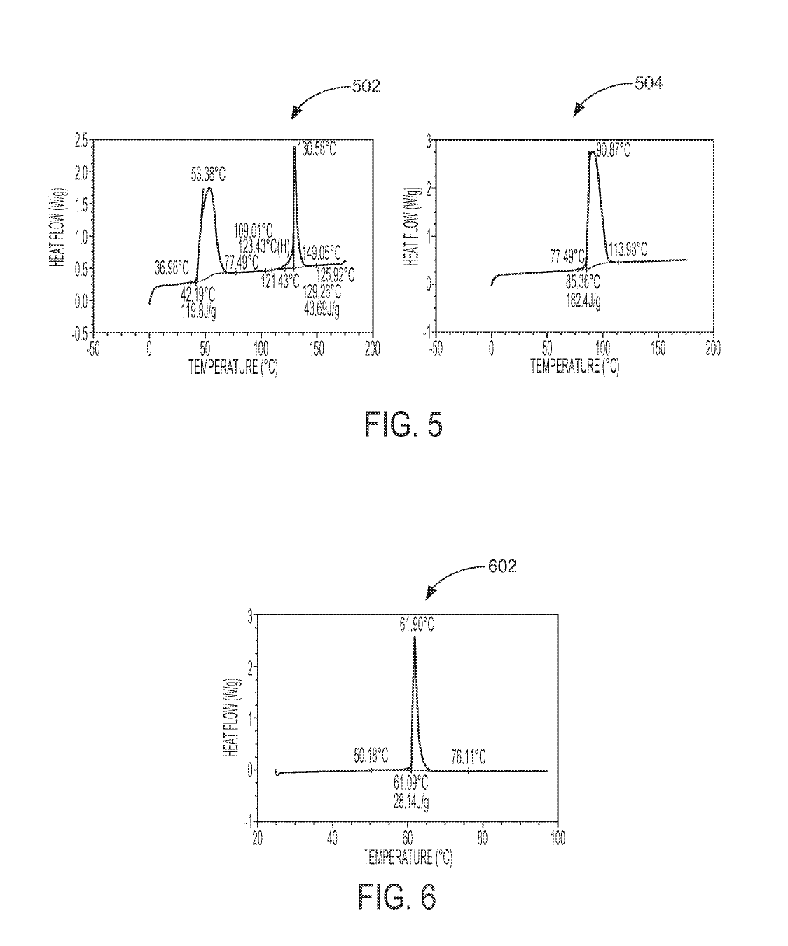

FIG. 5 schematically illustrates graphs 502, 504 showing phase transition characteristics of some example solid-solid phase change materials, in accordance with some embodiments. Graphs 502, 504 depict heat flow in Watts/gram (W/g) according to temperature (° C.). Graph 502 depicts phase transition characteristics of NPG and graph 504 depicts phase transition characteristics of PG. Mixtures of NPG and PG may provide a range of threshold temperature from about 54° C. to about 91° C.

FIG. 6 schematically illustrates a graph 602 showing phase transition characteristics of Field's metal, in accordance with some embodiments. Graph 602 depicts heat flow (W/g) according to temperature (° C.). The transition temperature is about 62° C.

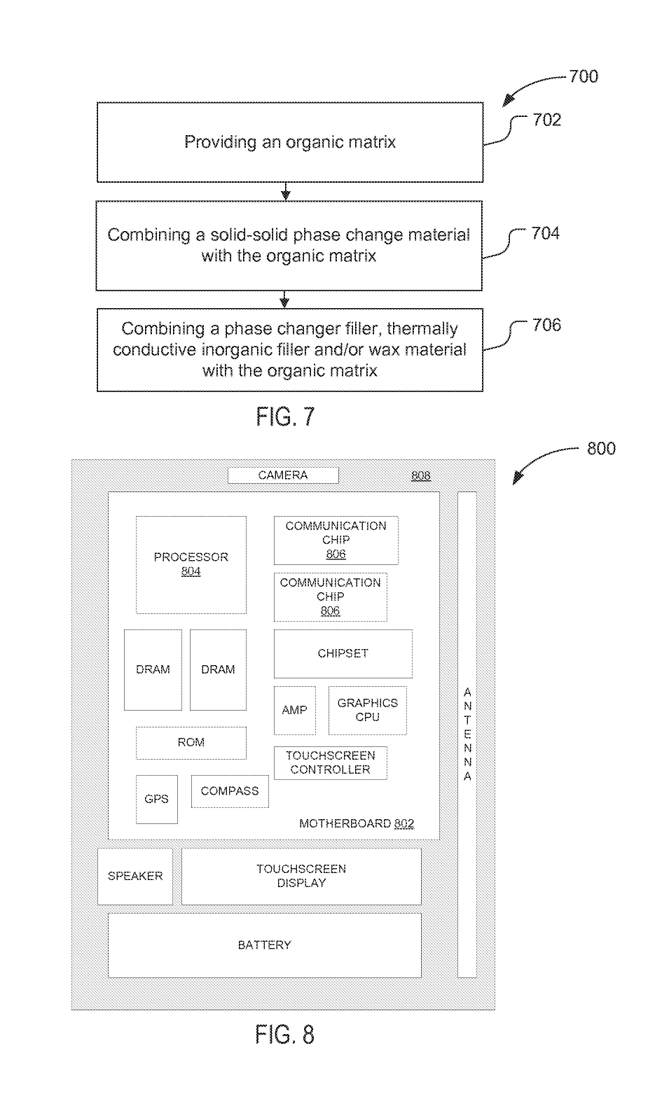

FIG. 7 schematically illustrates a flow diagram for a method 700 of fabricating an energy storage material, in accordance with some embodiments. The method 700 may comport with embodiments described in connection with FIGS. 1-4 and vice versa.

At 702, the method 700 may include providing an organic matrix (e.g., organic matrix 302 of FIG. 3). The organic matrix may include a polymer backbone such as, for example, PDMS or AMS. Other suitable polymer backbone materials may be used in other embodiments.

At 704, the method 700 may include combining a solid-solid phase change material (e.g., solid-solid phase change material 304 of FIG. 3) with the organic matrix. In some embodiments, the solid-solid phase change material may include a polyol dispersed in the organic matrix that is formulated to change crystalline structure and absorb heat while remaining a solid at a threshold temperature associated with operation of an IC die.

At 706, the method 700 may include combining a phase change filler (e.g., solid-liquid phase change material 306 of FIG. 3), thermally conductive inorganic filler (e.g., inorganic filler 310 of FIG. 3), and/or wax material (e.g., wax material 308 of FIG. 3) with the organic matrix. In some embodiments, the phase change filler may be combined with the organic matrix to change from solid to liquid phase at a temperature that is greater than the threshold temperature of the solid-solid phase change material. In some embodiments, the thermally conductive inorganic filler may be combined with the organic matrix to provide a heat percolation path through the organic matrix. In some embodiments, the wax material may be cross-linked with material of the organic matrix.

One example embodiment of method 700 may include mixing of the solid-solid phase change material together with phase change filler, thermally conductive inorganic filler and other additives such as wax into the monomer or oligomers of matrix resin followed by curing of the matrix. Other examples of mixing methods could also be employed such as solvent based mixing along with sonication for better filler dispersion, followed by solvent removal and curing of the organic matrix polymer.

Various operations are described as multiple discrete operations in turn, in a manner that is most helpful in understanding the claimed subject matter. However, the order of description should not be construed as to imply that these operations are necessarily order dependent.

Embodiments of the present disclosure may be implemented into a system using any suitable hardware and/or software to configure as desired. FIG. 8 schematically illustrates a computing device 800 that includes an IC assembly (e.g., IC assembly 100 of FIG. 1) as described herein, in accordance with some embodiments. The computing device 800 may house a board such as motherboard 802 (e.g., in housing 808). The motherboard 802 may include a number of components, including but not limited to a processor 804 and at least one communication chip 806. The processor 804 may be physically and electrically coupled to the motherboard 802. In some implementations, the at least one communication chip 806 may also be physically and electrically coupled to the motherboard 802. In further implementations, the communication chip 806 may be part of the processor 804.

Depending on its applications, computing device 800 may include other components that may or may not be physically and electrically coupled to the motherboard 802. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

The communication chip 806 may enable wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Institute for Electrical and Electronic Engineers (IEEE) standards including WiGig, Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wireless access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 806 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 806 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 806 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 806 may operate in accordance with other wireless protocols in other embodiments.

The computing device 800 may include a plurality of communication chips 806. For instance, a first communication chip 806 may be dedicated to shorter range wireless communications such as WiGig, Wi-Fi and Bluetooth and a second communication chip 806 may be dedicated to longer range wireless communications such as GPS, EDGE, GPRS, CDMA, WiMAX, LTE, EV-DO, and others.

The processor 804 of the computing device 800 may be a die of an IC assembly (e.g., IC assembly 100 of FIGS. 1-2) as described herein. For example, the circuit board 122 of FIG. 1 may be a motherboard 802 and the processor 804 may be a die 102 mounted on IC substrate 121 of FIG. 1. The IC substrate 121 and the motherboard 802 may be coupled together using package-level interconnects such as solder balls 112. Other suitable configurations may be implemented in accordance with embodiments described herein. The term “processor” may refer to any device or portion of a device that processes electronic data from registers and/or memory to transform that electronic data into other electronic data that may be stored in registers and/or memory.

The communication chip 806 may also include a die (e.g., RF die) that may be part of an IC assembly (e.g., IC assembly 100 of FIGS. 1-2) as described herein. In further implementations, another component (e.g., memory device or other integrated circuit device) housed within the computing device 800 may include a die of an IC assembly (e.g., IC assembly 100 of FIGS. 1-2) as described herein.

Energy storage material (e.g., energy storage material 300 of FIG. 3) may be disposed as a heat transfer layer on any of the dies described in connection with the computing device 800. In some embodiments, the energy storage material may be disposed on a substrate (e.g., any suitable surface) of the computing device 800.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. The computing device 800 may be a mobile computing device in some embodiments. In further implementations, the computing device 800 may be any other electronic device that processes data.

### Examples

According to various embodiments, the present disclosure describes an energy storage material. Example 1 of an energy storage material may include an organic matrix and a solid-solid phase change material dispersed in the organic matrix, the solid-solid phase change material to change crystalline structure and absorb heat while remaining a solid at a threshold temperature associated with operation of an integrated circuit (IC) die. Example 2 may include the energy storage material of Example 1, wherein the organic matrix comprises silicone. Example 3 may include the energy storage material of Example 2, wherein the organic matrix comprises polydimethylsiloxane (PDMS) or alkyl methyl silicone (AMS). Example 4 may include the energy storage material of Example 1, wherein the solid-solid phase change material comprises a polyol. Example 5 may include the energy storage material of Example 4, wherein the polyol comprises 2,2-dimethyl-1,3-propanediol, neopentyl glycol, 1,1,1-tris(hydroxymethyl)ethane or pentaglycerine. Example 6 may include the energy storage material of Example 5, wherein the polyol comprises a mixture of neopentyl glycol and pentaglycerine. Example 7 may include the energy storage material of any of Examples 1-6, further comprising a thermally conductive inorganic filler to provide a heat percolation path through the organic matrix. Example 8 may include the energy storage material of any of Examples 1-6, further comprising a wax material cross-linked with the organic matrix. Example 9 may include the energy storage material of any of Examples 1-6, further comprising a phase change filler to change from solid to liquid phase at a temperature that is greater than the threshold temperature. Example 10 may include the energy storage material of any of Examples 1-6, wherein the threshold temperature is in the range from 30° C. to 90° C. Example 11 may include the energy storage material of Example 10, wherein the threshold temperature is in the range of 35° C. to 45° C.

According to various embodiments, the present disclosure describes an apparatus. Example 12 of an apparatus may include a substrate of a mobile device and a heat transfer layer coupled with the substrate, the heat transfer layer including an organic matrix and a solid-solid phase change material dispersed in the organic matrix, the solid-solid phase change material to change crystalline structure and absorb heat while remaining a solid at a threshold temperature associated with operation of an integrated circuit (IC) die. Example 13 may include the apparatus of Example 12, wherein the substrate is a surface of an integrated circuit (IC) die and the heat transfer layer is a gap pad thermally coupled with the surface of the IC die. Example 14 may include the apparatus of Example 12, wherein the substrate comprises housing of the mobile device. Example 15 may include the apparatus of Example 12, wherein the substrate comprises a display of the mobile device. Example 16 may include the apparatus of Example 12, wherein the substrate is a thermally conductive sheet. Example 17 may include the apparatus of Example 16, wherein the thermally conductive sheet includes copper, graphene, or aluminum and has a thickness less than 100 microns. Example 18 may include the apparatus of Example 16, further comprising a heat insulator layer disposed between the heat transfer layer and the thermally conductive sheet.

According to various embodiments, the present disclosure describes a method. Example 19 of a method may include providing an organic matrix and combining a solid-solid phase change material with the organic matrix, the solid-solid phase change material to change crystalline structure and absorb heat while remaining a solid at a threshold temperature associated with operation of an integrated circuit (IC) die. Example 20 may include the method of Example 19, further comprising combining a thermally conductive inorganic filler with the organic matrix to provide a heat percolation path through the organic matrix. Example 21 may include the method of Example 19, further comprising cross-linking a wax material with the organic matrix. Example 22 may include the method of any of Examples 19-21, further comprising combining a phase change filler with the organic matrix, the phase change filler to change from solid to liquid phase at a temperature that is greater than the threshold temperature.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

1-22. (canceled)

23. An energy storage material comprising:
an organic matrix; and
a solid-solid phase change material dispersed in the organic matrix, the solid-solid phase change material to change crystalline structure and absorb heat while remaining a solid at a threshold temperature associated with operation of an integrated circuit (IC) die.

24. The energy storage material of claim 23, wherein the organic matrix comprises silicone.

25. The energy storage material of claim 24, wherein the organic matrix comprises polydimethylsiloxane (PDMS) or alkyl methyl silicone (AMS).

26. The energy storage material of claim 23, wherein the solid-solid phase change material comprises a polyol.

27. The energy storage material of claim 26, wherein the polyol comprises 2,2-dimethyl-1,3-propanediol, neopentyl glycol, 1,1,1-tris(hydroxymethyl)ethane or pentaglycerine.

28. The energy storage material of claim 27, wherein the polyol comprises a mixture of neopentyl glycol and pentaglycerine.

29. The energy storage material of claim 23, further comprising:
a thermally conductive inorganic filler to provide a heat percolation path through the organic matrix.

30. The energy storage material of claim 28, further comprising:
a wax material cross-linked with the organic matrix.

31. The energy storage material of claim 23, further comprising:
a phase change filler to change from solid to liquid phase at a temperature that is greater than the threshold temperature.

32. The energy storage material of claim 23, wherein the threshold temperature is in the range from 30° C. to 90° C.

33. The energy storage material of claim 31, wherein the threshold temperature is in the range of 35° C. to 45° C.

34. An apparatus comprising:
a substrate of a mobile device; and
a heat transfer layer coupled with the substrate, the heat transfer layer including:
an organic matrix; and
a solid-solid phase change material dispersed in the organic matrix, the solid-solid phase change material to change crystalline structure and absorb heat while remaining a solid at a threshold temperature associated with operation of an integrated circuit (IC) die.

35. The apparatus of claim 34, wherein the substrate is a surface of an integrated circuit (IC) die and the heat transfer layer is a gap pad thermally coupled with the surface of the IC die.

36. The apparatus of claim 34, wherein the substrate comprises housing of the mobile device.

37. The apparatus of claim 34, wherein the substrate comprises a display of the mobile device.

38. The apparatus of claim 34, wherein the substrate is a thermally conductive sheet.

39. The apparatus of claim 38, wherein the thermally conductive sheet includes copper, graphene, or aluminum and has a thickness less than 100 microns.

40. The apparatus of claim 38, further comprising a heat insulator layer disposed between the heat transfer layer and the thermally conductive sheet.

41. A method comprising:
providing an organic matrix; and
combining a solid-solid phase change material with the organic matrix, the solid-solid phase change material to change crystalline structure and absorb heat while remaining a solid at a threshold temperature associated with operation of an integrated circuit (IC) die.

42. The method of claim 41, further comprising:
combining a thermally conductive inorganic filler with the organic matrix to provide a heat percolation path through the organic matrix.

43. The method of claim 41, further comprising:
cross-linking a wax material with the organic matrix.

44. The method of claim 41, further comprising:
combining a phase change filler with the organic matrix, the phase change filler to change from solid to liquid phase at a temperature that is greater than the threshold temperature.
